(19) United States
(12) Patent Application Publication
(10) Pub. No.: US 2025/0239990 A1
(43) Pub. Date: Jul. 24, 2025

(54) COMPACTLY PARALLELIZED FILTER STRUCTURE

(71) Applicant: Murata Manufacturing Co., Ltd., Nagaokakyo-shi (JP)

(72) Inventors: Bryan KIMBRELL, Santa Barbara, CA (US); Greg DYER, Santa Barbara, CA (US); Timothy PALOMO, Foster City, CA (US)

(21) Appl. No.: 18/986,217

(22) Filed: Dec. 18, 2024

Related U.S. Application Data
(60) Provisional application No. 63/614,811, filed on Dec. 26, 2023.

(51) Int. Cl. H03H 9/17; H03H 9/13; H03H 9/56

(52) U.S. Cl. CPC H03H 9/173; H03H 9/133; H03H 9/568

(57) ABSTRACT

A filter device is provided that includes at least two resonators connected in parallel that each include a substrate, a piezoelectric layer attached either directly or via one or more intermediate layers to the substrate, and an interdigital transducer (IDT) at the piezoelectric layer, the IDT including a plurality of interleaved fingers The resonators include a physical layout such that lengths of the resonators extend in a first direction that is substantially orthogonal to a second direction of the interleaved fingers, a position of a first resonator is offset in the second direction from a position of a second resonator, such that the respective lengths of the resonators are not aligned in a same axis in the first direction, and the length of the first resonator is offset in the first direction from the length of the second resonator.

### CROSS REFERENCE TO RELATED APPLICATIONS

The current application claims priority to U.S. Patent Provisional Application No. 63/614,811, filed Dec. 26, 2023, the entire contents of which are hereby incorporated by reference.

### TECHNICAL FIELD

This disclosure relates to radio frequency filters using acoustic wave resonators, and more specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The transversely-excited film bulk acoustic resonator (XBAR) is an acoustic resonator structure for use in microwave filters. An XBAR resonator typically comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, bandpass filters, duplexers, and multiplexers. XBARs are well suited for use in filters for communications bands with frequencies above 3 GHZ.

### SUMMARY

Currently, design rules and die size limit the dimensions of acoustic resonators, including limiting the length of a resonator aperture defined by an area where the interleaved fingers of the resonator overlap. On the other hand, reducing the length of the resonator apertures may result in performance improvements, such as reduced parasitic electrical resistance, improved heat conduction, and mitigation of thermomechanical stresses. As further described below, a compactly parallelized resonator structure may enable optimal resonator aperture dimensions while maintaining conformance with process and product size constraints. In other words, the compactly parallelized resonator structures described herein may preserve the same overall device area and length while reducing aperture lengths of the resonators of the device, thereby taking advantage of the performance improvements associated with narrower resonator apertures.

According to an exemplary aspect, a filter device is provided that includes at least two resonators electrically connected in parallel. Moreover, each of the at least two resonators includes a piezoelectric layer, and an interdigital transducer (IDT) having a pair of busbars that extend in a first direction and a plurality of interleaved fingers extending from the pair of busbars and that are on a surface of the piezoelectric layer. In this aspect, at least one busbar of the pair of busbars of a first resonator of the at least two resonators overlaps at least one busbar of the pair of busbars of a second resonator of the at least two resonators in a second direction substantially orthogonal to the first direction, and the pair of busbars of the first resonator does not overlap the pair of busbars of the second resonator in the first direction.

In another exemplary aspect of the filter device, the first direction extends along a first axis and the respective pairs of busbars of the first and second resonators overlap in the second direction, such that a first imaginary line extending in a second axis perpendicular to the first axis intersects the at least one busbar of both the first resonator and the second resonator.

In another exemplary aspect of the filter device, a portion of the second resonator is not aligned with a portion of the first resonator in a plan view such that a second imaginary line extending in the second direction intersects the portion of the first resonator and not the portion of the second resonator.

In another exemplary aspect of the filter device, the at least two resonators comprise a physical layout such that: (i) lengths of the at least two resonators extend in the first direction and the plurality of interleaved fingers extend in the second direction, and (ii) a position of the first resonator is offset in the second direction from a position of the second resonator of the at least two resonators, such that the respective lengths of the at least two resonators are not aligned in a same axis in the first direction, and (iii) the length of the first resonator is offset in the first direction from the length of the second resonator, such that the respective lengths of the first and second resonators only partially overlap each in the second direction.

In another exemplary aspect of the filter device, each of the at least two resonators comprise a substrate, and the piezoelectric layer attached to the substrate by one or more intermediate layers.

In another exemplary aspect of the filter device, the lengths of each of the first resonator and the second resonator are defined by a length of the at least one busbar of the pair of busbars, respectively.

In another exemplary aspect of the filter device, the lengths of each of the first resonator and the second resonator are defined by a distance between outermost fingers of the plurality of interleaved fingers of the IDT of the respective resonator.

In another exemplary aspect of the filter device, each of the at least two resonators comprises a cavity in at least one of the substrate and the one or more intermediate layers, each cavity comprising opposing ends in the first direction, and the length of each of the first resonator and the second resonator is defined by a distance between the opposing ends of the cavity in the first direction.

In another exemplary aspect of the filter device, the at least two resonators are sub-resonators of a bulk acoustic resonator of a ladder filter circuit each have a same number of interleaved fingers of the IDT and a substantially same length as each other.

In another exemplary aspect of the filter device, the piezoelectric layer and the IDT of each of the at least two resonators are configured such that radio frequency signals applied to the IDT excites a primarily shear acoustic mode in the piezoelectric layer, the primarily shear acoustic mode being a bulk shear mode in which acoustic energy propagates along a direction substantially orthogonal to a surface of the piezoelectric layer, which is orthogonal to a direction of an electric field excited primarily laterally in the piezoelectric layer created by the interleaved fingers of the IDT.

In yet another exemplary aspect, a filter device is provided that includes at least two resonators electrically connected in parallel. In this aspect, each of at least two resonators includes a piezoelectric layer, and an interdigital transducer (IDT) including a plurality of interleaved fingers on the piezoelectric layer. Moreover, lengths of the at least two resonators extend in a first direction, the length of a first resonator of the at least two resonators is offset in a second direction orthogonal to the first direction from the length of a second resonator of the at least two resonators, such that the at least two resonators are not aligned in a same axis that extends in the first direction, and the length of the first resonator is offset in the first direction from the length of the second resonator, such that the lengths of the first and second resonators partially overlap each other relative to the second direction.

In another exemplary aspect of the filter device, a portion of the second resonator is aligned with a portion of the first resonator in a plan view such that a first imaginary line extending in the second direction intersects the respective portions of the first and second resonators, and the second resonator includes an additional portion that is not aligned with an additional portion of the first resonator in the plan view such that a second imaginary line extending in the second direction intersects the additional portion of only one of the first resonator and the second resonator.

In another exemplary aspect of the filter device, the IDT of each of the first resonator and the second resonator comprise a pair of busbars extending substantially in the first direction, and the lengths of each of the first resonator and the second resonator are defined by a length of at least one busbar of the busbars of each of the first and second resonators.

In another exemplary aspect of the filter device, each of the at least two resonators comprise a substrate, and the piezoelectric layer attached to the substrate by one or more intermediate layers, and each of the at least two resonators comprises a cavity in at least one of the substrate and the one or more intermediate layers, each cavity comprising opposing ends in the first direction, and the length of each of the first resonator and the second resonator is defined by a distance between the opposing ends of the cavity in the first direction.

In another exemplary aspect of the filter device, the at least two resonators include three resonators, a portion of the second resonator overlaps a portion of the first resonator in a plan view such that a first imaginary line extending in the second direction intersects the respective portions of the first and second resonators, an additional portion of the second resonator overlaps a portion of a third resonator in the plan view such that a second imaginary line extending in the second direction intersects the additional portion of the second resonator and the portion of the third resonator and does not intersect the first resonator, and the first resonator and the third resonator are positioned such that a third imaginary line extending in the first direction intersects the first and third resonators and not the second resonator.

In yet another exemplary aspect, a filter device is provided that includes a plurality of resonators electrically connected in parallel. In this aspect, each of the plurality of resonators includes an interdigital transducer (IDT) on a surface of a piezoelectric layer and having at least one busbar extending in a first direction, each IDT having a length measured in the first direction that is defined by a distance between a first end and a second end of the at least one busbar in the first direction, and the filter device corresponding to a total IDT length that is equal to a sum of the lengths of the IDT of each of the plurality of resonators. Moreover, the length of a first resonator of the plurality of resonators at least partially overlaps the length of a second resonator of the plurality of resonators in the second direction, such that the first resonator and the second resonator are not aligned in a same axis that extends in the first direction, and a distance in the first direction between a pair of imaginary lines extending in the second direction that intersect the first end of the at least one busbar of the first resonator and the second end of the at least one busbar of the second resonator is less than the total IDT length.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6A is a schematic diagram of a single acoustic resonator having a predefined length and width.

FIG. 6B is a schematic diagram of a parallelized structure including two acoustic resonators according to an exemplary aspect.

FIG. 6C is a schematic diagram of a parallelized structure including three acoustic resonators according to an exemplary aspect.

FIG. 6D is a schematic diagram of a parallelized structure including four acoustic resonators according to an exemplary aspect.

FIG. 6E is a schematic diagram of a parallelized structure including three acoustic resonators according to an exemplary aspect.

FIG. 7A is a schematic block diagram of a single acoustic resonator area and an associated thermal transport relationship.

FIG. 7B is a schematic block diagram of a parallelized structure including three acoustic resonator areas and an associated thermal transport relationship according to an exemplary aspect.

FIG. 8 is an exemplary graph showing series fusing failure points of various aperture dimension variations.

FIG. 9 is an exemplary graph of performance differences between single resonator and parallelized resonator structures due to differences in layout parasitic measurements and other factors.

FIG. 10A is an electrical schematic showing parasitic parameters associated with a parallelized multi-resonator configuration.

FIG. 10B is an electrical schematic showing parasitic parameters associated with a single resonator configuration.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

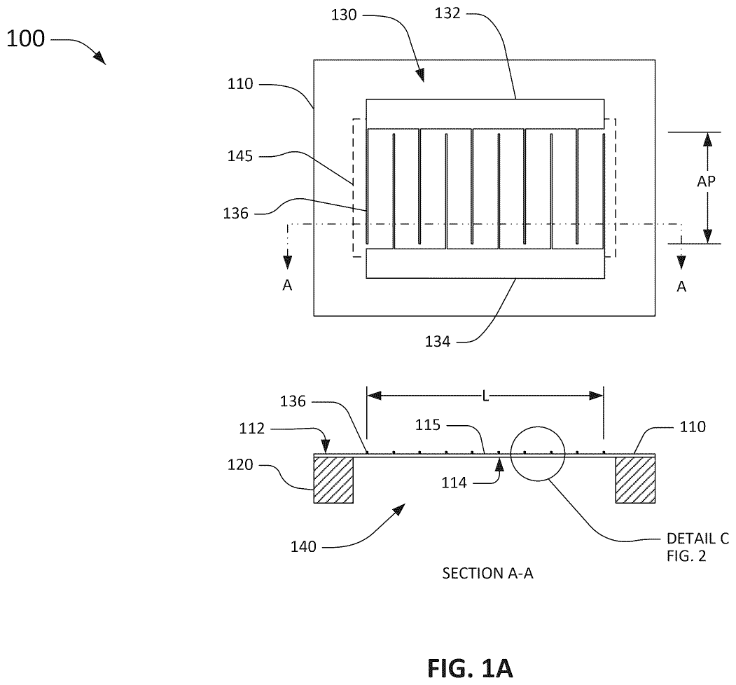

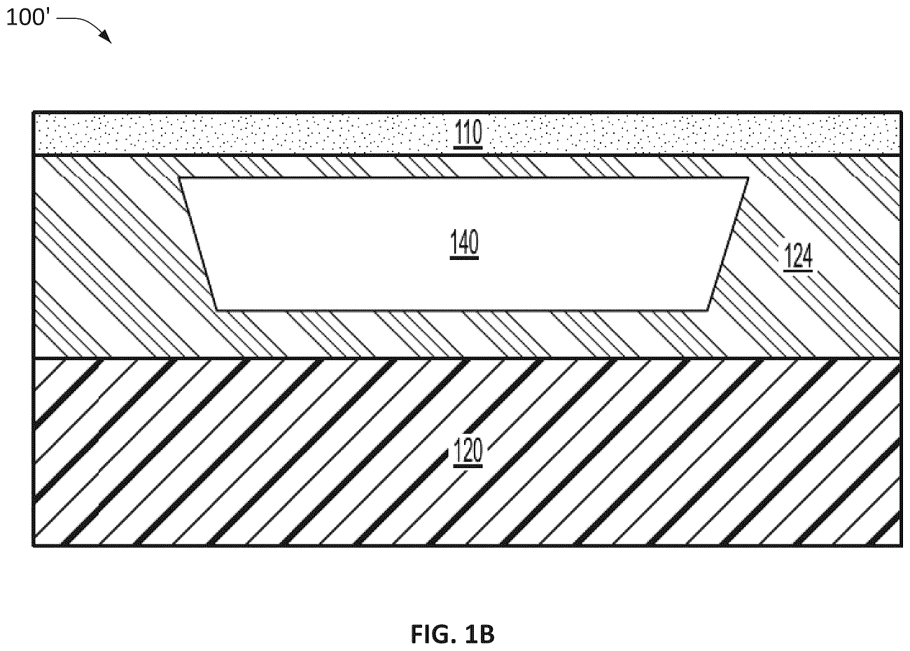

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

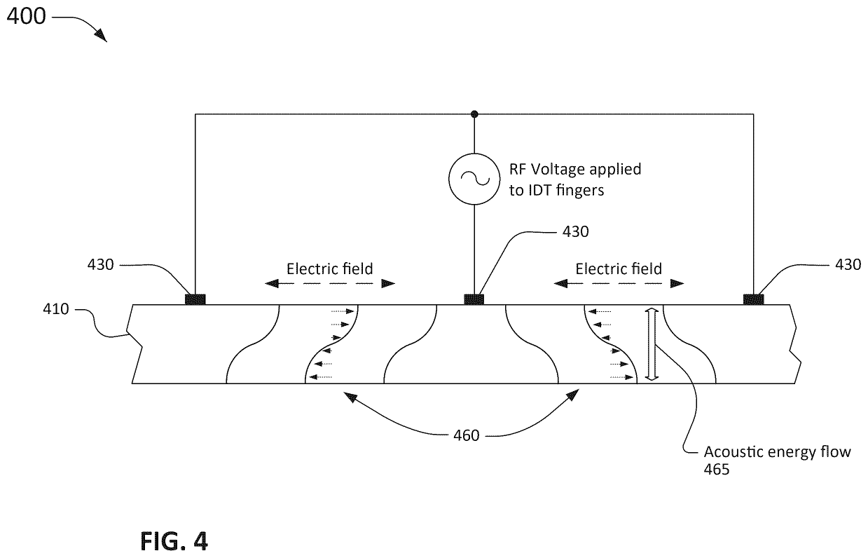

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

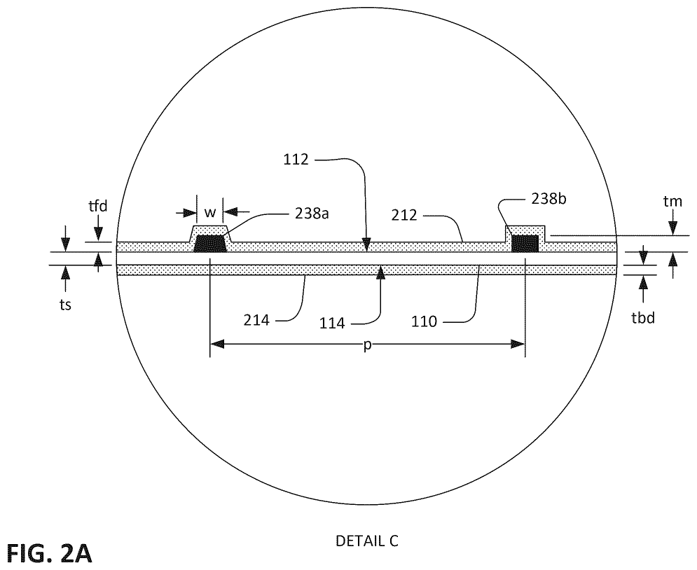

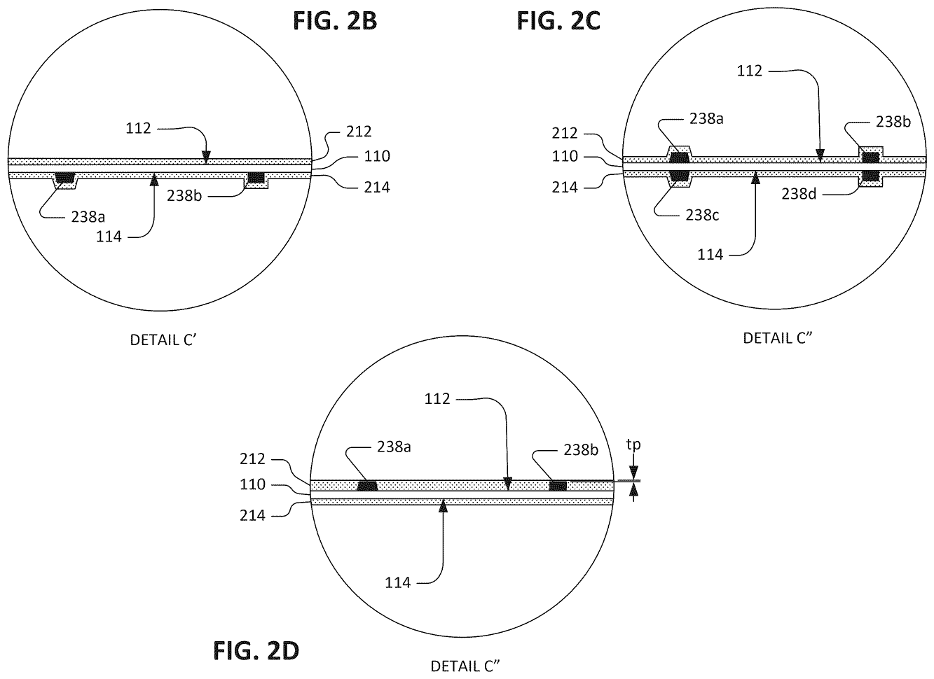

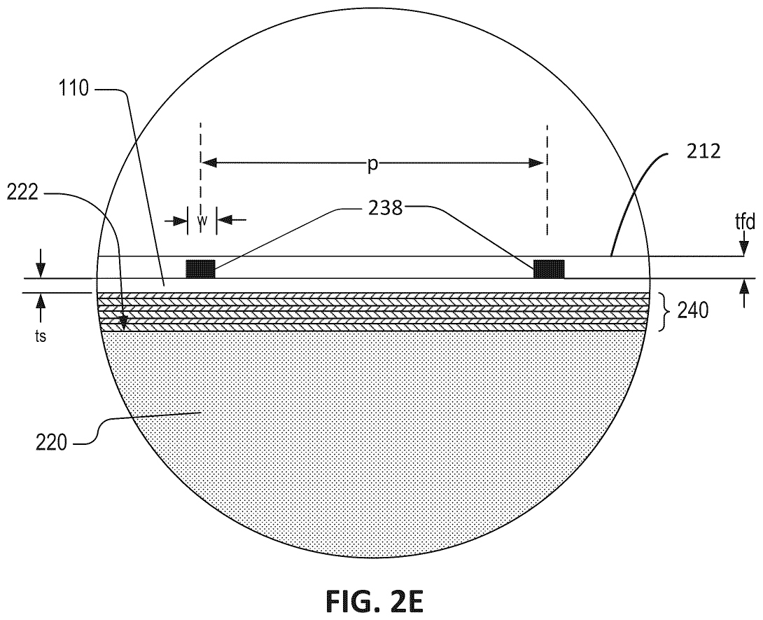

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHZ, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238, 238a, and 238b, may be disposed on a surface of the front side 112 of the piezoelectric layer 110. Alternatively, IDT fingers, such as IDT finger 238, 238a, and 238b, may be disposed in grooves formed in the surface of the front side 112. The grooves may extend partially through the piezoelectric layer. Alternatively, the grooves may extend completely through the piezoelectric layer.

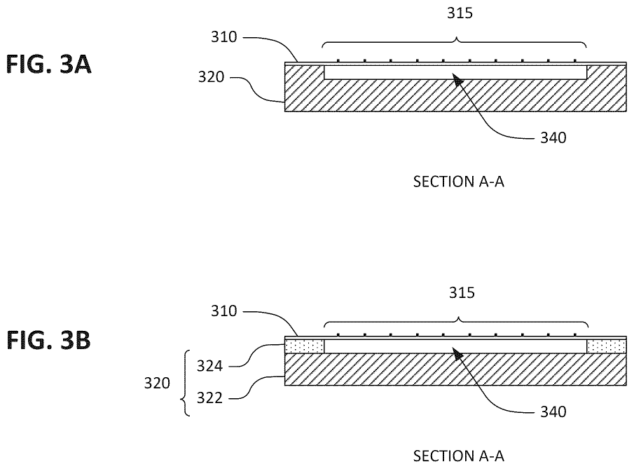

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

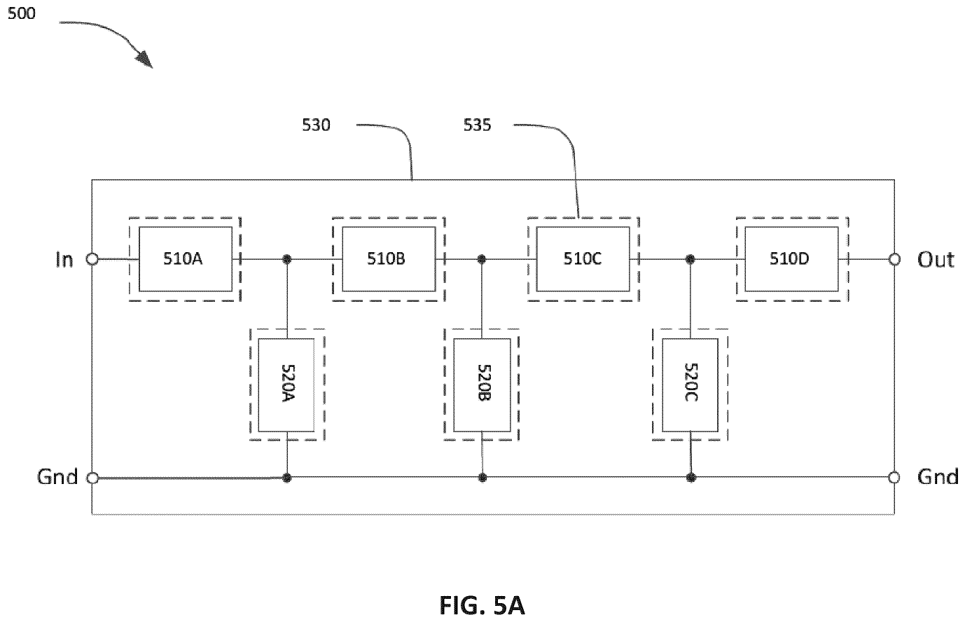

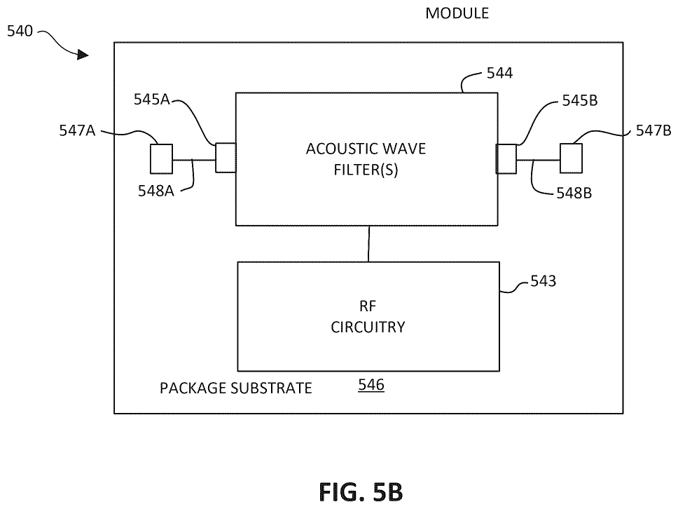

FIG. 5A is a schematic circuit diagram and layout for a high frequency bandpass filter 500 using XBARs, such as the general XBAR configuration 100 (e.g., the bulk acoustic resonators) described above, for example. The filter 500 has a conventional ladder filter architecture, which may include a split-ladder filter architecture wherein the filter is split between multiple chips, that has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of four series and three shunt resonators is an example. A filter may have more or fewer than seven total resonators, more or fewer than four series resonators, and more or fewer than three shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and other contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A, 510B, 510C and 510D and the shunt resonators 520A, 520B and 520C can have an XBAR configuration as described above with respect to FIGS. 1A-2D in which a diaphragm with IDT fingers spans over a cavity. Alternatively, each of the series resonators 510A, 510B, 510C, 510D and the shunt resonators 520A, 520B, and 520C can have an XBAR configuration in which the series resonators 510A, 510B, 510C, 510D and/or the shunt resonators 520A, 520B, and 520C can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

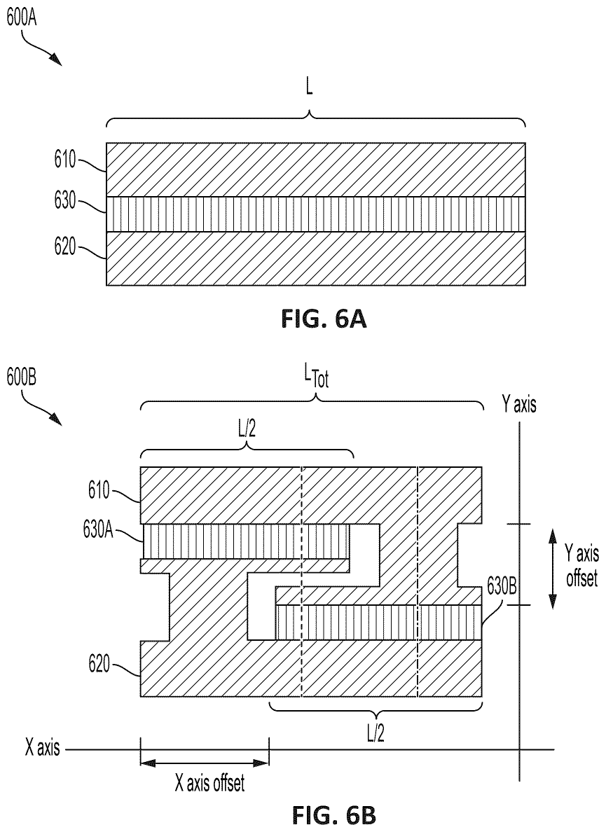

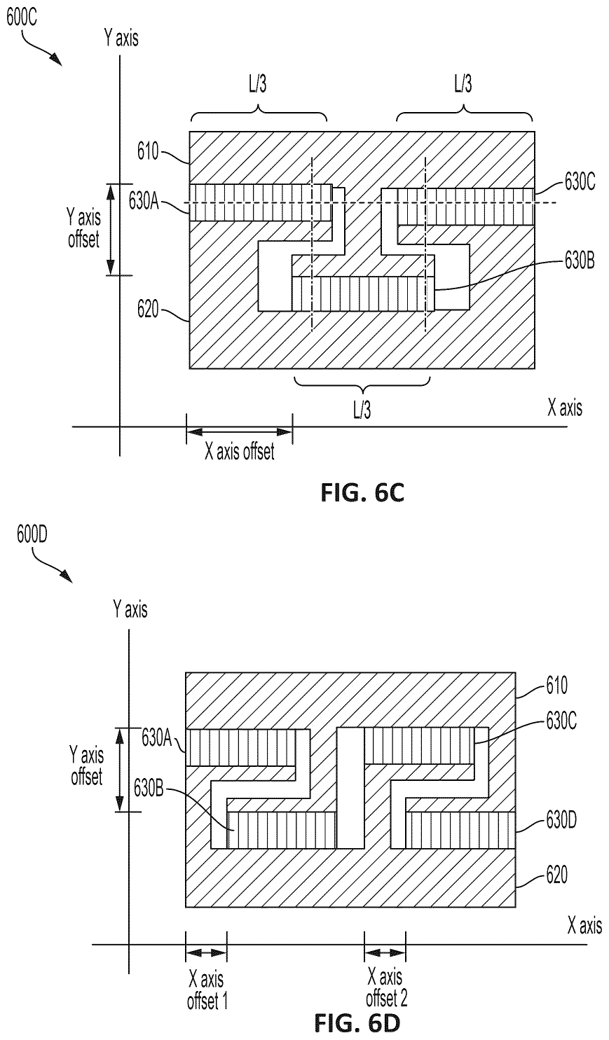

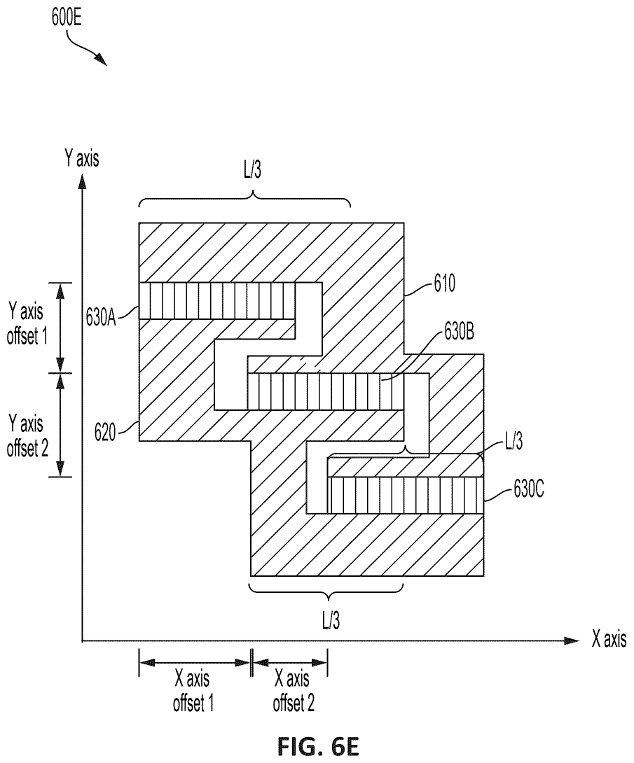

According to an exemplary aspect, an RF filter device, such as filter 500 described above with respect to FIG. 5A or the acoustic wave filters 544 described above with respect to FIG. 5B, can be configured to use a parallelized resonator structure or configuration to improve filter performance by reducing the aperture lengths of each individual resonator device. FIGS. 6A and 6B illustrate a parallelization that may result in splitting a single resonator by creating an equivalent parallelized structure with two resonators (or sub-resonators) having shorter apertures and/or lengths that also decreases the overall device area (e.g., in a plan view thereof). For example, a single resonator may be divided and configured as two or more sub-resonators as part of the bulk acoustic resonator of a ladder filter circuit (e.g., configured as an acoustic wave filter 544 of FIG. 5B) in which each of the sub-resonators have a same number of interleaved fingers of the IDT and a substantially same length as each other. Moreover, dividing a resonator (e.g., an XBAR) as described herein into multiple sub-resonators has a primary benefit of reducing the peak stress that would occur if each XBAR had a single large diaphragm. That is, at least two sub-resonators can share the same diaphragm over a single cavity, which effectively reduces the mechanical stress. Moreover, the parallelization techniques described herein provide for further reduced overall area of the filter structure.

FIG. 6A shows a single resonator structure 600A having a length L and can also be considered as having a width that corresponds to the IDT aperture or the distance between opposing busbars, for example. The schematic of FIG. 6A is representative of a filter device including a resonator 600A including a single IDT having a single aperture, although the individual components of the resonator are not shown in detail. The resonator of FIG. 6A may have, for example, the XBAR configuration 100 including any of the configurations of FIGS. 1B-2E or any combination thereof.

The parallel lines shown in the single resonator structure 600A of FIG. 6A represent the aperture of the resonator, which is the defined by the interleaved fingers of the IDT 630, as described above. The length L of the resonator of FIG. 6A is measured in a direction perpendicular to the interleaved fingers of the IDT 630 (i.e., the length L is the longer dimension of the structure), while the width is measured in a direction parallel with the direction in which the interleaved fingers extend. The length L and width may respectively refer to the length and width of the aperture of the resonator structure of FIG. 6A. It is also noted that the first and second busbars of IDT 630 are coupled to wiring terminals 610 and 620, respectively, which are provided as electrical contacts for applying the voltages to acoustic resonator(s) as described herein. It is noted that for purposes of explaining the exemplary aspects, the IDT 630 is general described as resonator 600A or a single resonator structure. That is, when the disclosure refers to IDT 630, it is generally referring to a resonator having the single structure and vice versa.

Moreover, for purposes of this disclosure, the length of the busbars of each exemplary aspect is described as extending in the X axis direction or a first direction. The interleaving fingers generally extend from the pair of busbars in the Y axis direction or a second direction, which is orthogonal or perpendicular to the first direction.

The length L may correspond to the length L of the IDT shown in FIG. 1A, for example, and can be considered a distance in the first direction from a first end (e.g., a first finger) to a second end (e.g., a last finger) of the plurality of interleaved fingers of the IDT 630. Likewise, the width may correspond to the dimension AP (i.e., the aperture) shown in FIG. 1A. Alternatively, the length L and width may respectively refer to the length and width of the piezoelectric layer of the resonator structure of FIG. 6A. Other dimensions of the resonator of FIG. 6A, such as busbar dimensions for example, may correspond to length L and width in other exemplary aspects.

The length L and width corresponding to the single resonator structure 600A of FIG. 6A are determined based on design rules and performance requirements applicable to the resonator. While reducing the aperture length of a resonator, for example, an XBAR resonator as described above with respect to FIGS. 1A-3B, reduces parasitic resistance, improves heat conduction, and mitigates thermomechanical stresses, design rules and die size control the ultimate length of a resonator and its aperture. Conventionally, aperture lengths were only minimized to the extent that such changes could be accommodated by the design specifications of the filter device. However, as shown and described as follows with respect to FIGS. 6B-6E, the single resonator structure 600A of FIG. 6A may be replaced with parallelized structures and configurations to enable a more flexible filter design that allows for more optimized resonator aperture lengths. In particular the exemplary aspects shown in FIGS. 6B-6E provide for physical layouts of a plurality of acoustic resonators (e.g., XBARs) with various parallelized structures.

Specifically, FIG. 6B shows a dual-resonator structure 600B that can be part of a filter device and includes a physical layout that may replace the single resonator structure 600A of FIG. 6A according to an exemplary aspect. As shown in FIG. 6B, each of the two resonators 630A and 630B, which can be a pair of sub-resonators in an exemplary aspect, have the same width dimension as the single resonator structure of FIG. 6A, but the length of the IDT of each resonator 630A and 630B is half of length L (or a fraction) of the single resonator structure 600A of FIG. 6A. That is, the length of each resonator 630A and 630B of FIG. 6B is L/2.

According to an exemplary aspect, “resonator length” herein can refer to the length L of the IDT, as shown in FIG. 1A, which is defined by a distance between outermost fingers of the plurality of interleaved fingers of the IDT of the respective resonator. However, other exemplary aspects may consider resonator dimensions to correspond to, for example, piezoelectric layer dimensions or other resonator dimensions. For example, the length of each resonator can be the lengths of one busbar and/or both busbars of the respective resonators. Alternatively, the length of each resonator can be the distance between opposing ends in the first direction of a cavity in the first direction.

In general, in FIG. 6B, the two resonators (i.e., the top resonator 630A and the bottom resonator 630B) can generally have the configuration shown above with respect to acoustic resonator 100 of FIG. 1A. Moreover, the resonators according to the exemplary aspects may be implemented according to the various exemplary aspects in FIGS. 1A to 3B. As described herein, the interleaved fingers of each of the IDTS of resonators 630A and 630B extend orthogonally or substantially orthogonally to a pair of respective busbars. It should be appreciated that one or both the busbars may also have a length (e.g., in the length direction or X axis direction) that extends farther than the respective interleaved fingers.

As described below, the pair of offset acoustic resonators 630A and 630B (e.g., as shown in FIG. 6B) will partially overlap each other relative to the Y axis direction. In an exemplary aspect, the pair of acoustic resonators 630A and 630B can be implemented according to the configurations shown in FIGS. 1A and 1B as well as FIGS. 2A to 2D in which a diaphragm of the piezoelectric layer 110 is over a cavity 140. In this aspect, the pair of resonators are considered to overlap (relative to the first direction or X axis) when at least the respective cavities of the two resonators overlap each other. In other words, each cavity of each resonator can have ends (e.g., where the cavity extends into the one or more intermediate layers and/or the substrate) in the first direction. The length of each resonator can be defined as the distance from opposing ends in this first direction. Thus, the cavities can be considered as overlapping in the first direction when these cavities at least partially overlap with each other.

In a variation of this exemplary aspect, the busbars of the respective acoustic resonators can also at least partially overlap with each other. In another exemplary aspect, the interleaved fingers of each acoustic resonator will also partially overlap each other relative to the X axis direction, but in another aspect, only the respective cavities and/or the respective busbars overlap each other. Thus, according to an exemplary aspect, when the acoustic resonators 630A and 630B are said to overlap each other relative to the first direction (e.g., the X axis direction), this means that at least the cavities or at least one of the busbars are offset in the first direction and overlap each other in the second direction (e.g., the Y axis direction).

In another exemplary aspect, the pairs of busbars of each acoustic resonator can more generally be considered as wire routing (e.g., wire lines) that connects the interleaved fingers of each resonator to the respective electric potentials applied across the area of the resonators. In this exemplary aspect, the same principals described hereto as long as the acoustic resonators at least partially overlap relative to the second direction described herein.

In addition, the pair of acoustic resonators can be implemented as solidly mounted acoustic resonators according to the configuration shown in FIG. 2E in which the piezoelectric layer 110 is over a Bragg reflector (Bragg mirror or reflector) 240. In this aspect, the pair of resonators are considered to overlap (relative to the first direction or X axis) when at least the respective Bragg reflectors of the two resonators overlap each other relative to the X axis direction.

In any event, in the examples of FIGS. 6A-6E, the length L of the single resonator structure 600A of FIG. 6A can be evenly divided among the number of resonators used in each example. That is, the lengths of the resonators in the parallelized multi-resonator configurations may be equal to each other in an exemplary aspect. Moreover, the widths of the resonators in the parallelized multi-resonator configurations may also be equal to each other. However, other exemplary aspects may include multiple resonators with different lengths and/or widths, depending on device specifications.

As described below, a single resonator structure (e.g., resonator 600A) such as the one shown in FIG. 6A may have a total length that may be split among two or more resonators (e.g., resonators 630A and 630B) with shorter lengths such that a sum of the lengths of the resonators of the split structure is equal to the total length of the original single resonator structure 600A. For example, resonators 630A and 630B may each have a length L/2, which is half the length L of the resonator 600A in FIG. 6A. As described herein, positions of at least two resonators 630A and 630B in the split structure may be offset from each other at least in a direction parallel to the direction in which the interleaved fingers of the resonators extend.

As further shown in FIG. 6B, the two resonators 630A and 630B are electrically connected in parallel between wiring terminals 610 and 620 similar to the configuration described above with respect to FIG. 6A. In this aspect, the positions of the two resonators are offset from each other both horizontally (e.g., in a first direction) and vertically (e.g., in a second direction). For example, the position of the top resonator 630A in FIG. 6B is offset along the X axis (e.g., a first direction) from the position of the bottom resonator 630B. This offset (i.e., the “X axis offset”) is indicated relative to the positions of the leftmost edges of the respective IDTs of the two resonators 630A and 630B on the X axis of FIG. 6B. Likewise, the position of the top resonator is offset along the Y axis (e.g., a second direction) from the position of the bottom resonator in FIG. 6B. This offset (i.e., the “Y axis offset”) is indicated relative to the top edges of the respective IDTs of the two resonators 630A and 630B on the Y axis of FIG. 6B. However, alternative views and orientations are possible.

In the exemplary aspect of FIG. 6B, the Y axis extends in a direction parallel (or substantially parallel) with the direction in which the interleaved fingers of the resonators 630A and 630B extend and the X axis extends in a direction substantially perpendicular or orthogonal to the direction in which the interleaved fingers of the resonators extend, i.e., the lengthwise direction of the length L of the respective resonators. That is, in this exemplary aspect, lengths of the top and bottom resonators are measured along the X axis (i.e., first direction), which is substantially, or predominantly, orthogonal or perpendicular to the Y axis (i.e., second direction) in which the interleaved fingers of the IDTs of the top and bottom resonators extend. As described herein, for purposes of this disclosure, the terms “substantially” and/or “approximately” are used to take into account possible manufacturing tolerances, for example. In this context, the pair busbars of each IDT may extend generally in the X axis direction and parallel or substantially parallel to each other, meaning +10° or −10° of each other relative to a parallel direction. Likewise, the interleaved fingers of each IDT may extend generally in the Y axis direction and substantially parallel from the respective busbars. In this context, the interleaved fingers may extend in a direction either +10° or −10° of orthogonal of the respective busbar (i.e., 80° to 100°).

Accordingly, in the example of FIG. 6B, the position of one of the resonators (e.g., the bottom resonator 630B) is offset along the Y axis from a position of the other resonator (e.g., the top resonator 630A). Additionally, the position of one of the resonators (e.g., the bottom resonator 630B) is offset along the X axis from a position of the other resonator (e.g., the top resonator 630A). Thus, as shown, the top resonator 630A at least partially overlaps with the bottom resonator 630B along the X axis direction, but they do not overlap each other along the Y axis direction since they extend in a direction substantially parallel to each other. As such, the dual-resonator structure 600B includes at least two resonators 630A and 630B having a physical layout in which the lengths of the resonators extend in a first direction (e.g., the X axis) that is orthogonal to a second direction (e.g., the Y axis) in which the interleaved fingers of the IDTs of the resonators predominantly extend. Moreover, a position of a first resonator (e.g., the top resonator) is offset in the second direction (e.g., the Y axis) from a position of a second resonator (e.g., the bottom resonator), such that the respective lengths of the resonators are not aligned in a same axis (e.g., the X axis) in the first direction and thus do not overlap each other in the Y axis direction. Yet further, the first resonator (e.g., the top resonator) is offset in the first direction (e.g., the X axis) from the of the second resonator (e.g., the bottom resonator), such that the first and second resonators at least partially overlap each other relative to the first direction (e.g., the X axis). In an alternative aspect, it should be appreciated that the pair of resonators (e.g., the top and bottom resonators of FIG. 6B) entirely overlap each other relative to the X axis direction (i.e., the first direction). Moreover, in an exemplary aspect, the first resonator 630A and the second resonator 630B at least partially overlap each other when at least one busbar of the pair of busbars of the first resonator 630A overlaps or partially overlaps at least one busbar of the pair of busbars of the second resonator 630B in the second direction substantially orthogonal to the first direction. As noted above, the pair of busbars of the first resonator 630A does not overlap the pair of busbars of the second resonator 630B in the first direction.

Due to the offsets applied in both the X and Y directions to the positions of the first resonator 630A and the second resonator 630B in FIG. 6B, the resonators are positioned such that a portion of the top resonator (i.e., the right-most portion of the top resonator 630A) is aligned with a portion of the bottom resonator (i.e., the left-most portion of the bottom resonator). In other words, a portion of the bottom resonator 630B (e.g., a first portion of the bottom resonator) is directly below a portion of the top resonator 630A (e.g., a first portion of the top resonator) in the plan view of FIG. 6B. This alignment is such that an imaginary line (dashed line in FIG. 6B) in the XY plane (e.g., parallel to the substrate or the piezoelectric layer) and extending in the Y direction (second direction) passes through (i.e., intersects) the aligned portions of the respective IDTs (e.g., at least one busbar) of both the top resonator 630A and the bottom resonator 630B. In an exemplary aspect, the aligned portions of the top resonator 630A and the bottom resonator 630B may include at least a portion of the piezoelectric layers of the top and bottom resonators, respectively. In another exemplary aspect, the aligned portions may include a portion of an IDT of the top resonator 630A and/or a portion of an IDT of the bottom resonator 630B.

On the other hand, the first and second resonators 630A and 630B also have respective portions (e.g., an additional portion or second portion) that are not aligned with each other. For example, another imaginary line (dot-dash-dot line in the plan view of FIG. 6B) in the XY plane (e.g., parallel to the substrate or the piezoelectric layer) and extending in the Y direction passes through (i.e., intersects) only the IDT of the bottom resonator 630B and not the IDT of the top resonator 630A. A similar imaginary line may be drawn that extends in the Y direction parallel to the substrate (or the piezoelectric layer) and passes only through the top resonator 630A and not the bottom resonator 630B. As such, the respective additional portions of the first and second acoustic resonators 630A and 630B do not overlap each other in the second direction in the exemplary aspect. It is noted that when the length of the respective resonators 630A and 630B are defined by the length of the respective busbars, the imaginary line (dashed line in FIG. 6B) can pass through at least one busbar of each of the resonators 630A and 630B, but the other imaginary line (dot-dash-dot line in the plan view of FIG. 6B) passes through the busbars of only one of the resonators 630A and not the busbars of the other resonator 630B, for example, or vice versa.

Although FIGS. 6A and 6B are not drawn to scale, it is noted that the split parallel resonator structure of FIG. 6B has a shorter length than FIG. 6A, due to the overlapped portions of the top and bottom resonators on the X axis. In other words, each IDT of each resonator 630A and 630B (which generally can be considered a plurality of resonators) has a length L/2 measured in the first direction (i.e., the X axis direction) that is defined by a distance between a first end and a second end of the at least one busbar in the first direction. Moreover, the dual-resonator structure 600B can correspond to a total IDT length that is equal to a sum of the lengths L/2 of the IDTs of the plurality of resonators 630A and 630B. This length can equal the length L of the IDT of resonator 600A of FIG. 6A as described above. Moreover, in this aspect, the length (having a length L/2) of the first resonator 630A of the plurality of resonators at least partially overlaps the length (having a length L/2) of the second resonator 630B of the plurality of resonators in the second direction, such that the first resonator 630A and the second resonator 630B are not aligned in a same axis that extends in the first direction (i.e., the X axis direction). Moreover, a distance in the first direction between a pair of imaginary lines extending in the second direction (i.e., the Y axis direction) that intersect the first end of the at least one busbar of the first resonator 630A and the last end of the at least one busbar of the second resonator 630B is less than the total IDT length, i.e., length L. It is noted that this distance is annotated by L_{Tot} in FIG. 6B and that the imaginary lines would extend down from the bracket annotated as L_{Tot} in the second direction (i.e., the Y axis direction) to intersect with the left side of the IDT (e.g., the first finger) of resonator 630A and the right side of the IDT (e.g., the last finger) of resonator 630B. Accordingly, the distance or length by L_{Tot} is less than the length L of resonator 630 of FIG. 6A to provide a more compact filter structure as described herein.

According to the exemplary aspect, the split parallel resonator structure 600B (i.e., the dual-resonator structure) of FIG. 6B has the same shunt capacitance as the single resonator structure 600A of FIG. 6A. The particular resonator positions and offsets shown in FIG. 6B are exemplary and other resonator positions, offsets, and orientations are possible. For example, FIGS. 6C-6E show other exemplary parallel resonator structures each having a physical layout that reduces the aperture length of the original single resonator structure of FIG. 6A.

In each of the parallel resonator structures of FIGS. 6C-6E, the multiple resonators are electrically connected in parallel between two wiring terminals 610 and 620, similarly to the exemplary aspect of FIG. 6B. For example, in FIG. 6C, three resonators 630A, 630B and 630C (or three sub-resonators) are used, each having a length L/3 that is one third of the length L of the single resonator structure 600A of FIG. 6A, although the lengths can be less than L/3 in an alternative aspect. Moreover, the width of the resonators 630A-630C in the examples of FIGS. 6C-6E remains the same as width of the single resonator structure 600A of FIG. 6A.

In the example of FIG. 6C, the top and bottom resonator structure described above with respect to FIG. 6B is used. The Y axis offset and X axis offset with respect to the top and left edges, respectively, of the top resonators 630A and 630C and bottom resonator 60B are indicated in FIG. 6C, as in FIG. 6B. In addition to the resonators 630A and 630B, a second top resonator 630C is included in the configuration of FIG. 6C that is aligned with the resonator 630A along the X axis.

As in FIG. 6B, the offsets applied in both the X and Y directions in FIG. 6C configure the resonators to be positioned such that a portion of one of the top resonators (i.e., the right-most portion of the top left resonator 630A) overlaps a portion of the bottom resonator (i.e., the left-most portion of the bottom resonator 630B). In other words, a portion of the bottom resonator 630B is directly below a portion of the top left resonator 630A in the plan view of FIG. 6C. This alignment is such that an imaginary line (shown as a dashed line) extending parallel to the substrate in the Y direction may pass through (i.e., intersect) the aligned portions of IDTs of both the top left resonator 630A and the bottom resonator 630B.

In addition, a portion of the second top resonator (i.e., the left-most portion of the top right resonator 630C) overlaps a portion of the bottom resonator (i.e., the right-most portion of the bottom resonator 630B). In other words, a portion of the bottom resonator 630B is directly below a portion of the top right resonator 630A in the plan view of FIG. 6C. This alignment is such that an imaginary line (shown as a dash-dot-dash line) extending parallel to the substrate in the Y direction may pass through (e.g., intersect) the aligned portions of both the top right resonator 630C and the bottom resonator 630B. In this instance, the imaginary line (shown as a dash-dot-dash line) does not insect the top left resonator 630A, but instead only intersects the top right resonator 630C and the bottom resonator 630B. It is noted that the positions of the two top resonators 630A and 630C in FIG. 6C are aligned along the Y axis, such that an imaginary line (dashed line in FIG. 6C) extending in the X direction (i.e., the first direction) passes through (i.e., intersects) the IDTs of both of the top resonators 630A and 630C, but not resonator 630B relative to the first direction.

Thus, according to the exemplary aspect of FIG. 6C, a filter device 600C is provided that includes three resonators 630A, 630B and 630C in which a portion of the second resonator 630B overlaps a portion of the first resonator 630A in a plan view such that a first imaginary line extending in the second direction (i.e., the Y axis direction) intersects the respective portions of the first and second resonators 630A and 630B. Moreover, an additional portion of the second resonator 630B overlaps a portion of a third resonator 630C in the plan view such that a second imaginary line extending in the second direction (i.e., the Y axis direction) intersects the additional portion of the second resonator 630B and the portion of the third resonator 630A and does not intersect the first resonator 630A. Moreover, the first resonator 630A and the third resonator 630A are positioned such that a third imaginary line extending in the first direction (i.e., the X axis direction) intersects the first and third resonators 630A and 630C and not the second resonator 630B.

In the exemplary aspect of FIG. 6D, the dual offset resonator structure described above with respect to FIG. 6B is duplicated such that four resonators 630A, 630B, 630C and 630D of a filter device 600D are configured, each having a length L/4 that is one fourth of the length L of the single resonator structure 600A of FIG. 6A. The X axis and Y axis offsets of the configurations described in FIGS. 6B-6E may be optimized based on design parameters and device dimensions. For example, each of resonators 630B and 630D can be offset in the second direction by the Y axis offset. Moreover, resonator 630B can be offset in the first direction from resonator 630A by X axis offset 1, and resonator 630D can be offset in the first direction from resonator 630C by X axis offset 2. X axis offset 1 can be the same length or distance as X axis offset 2 in an exemplary aspect, but may also be different lengths or distances in an alternative aspect. In this aspect, the portions of the top and bottom resonators that are aligned (and non-aligned) with each other may be optimized according to performance and size requirements. Again, the four resonators 630A to 630D (or sub-resonators) are electrically connected in parallel between wiring terminals 610 and 620 similar to the configuration described above with respect to FIG. 6A.

FIG. 6E shows an exemplary aspect of a cascaded parallel structure of a filter device 600E, in which three resonators 630A, 630B and 630C are all offset vertically and horizontally from each other. As shown, resonator 630B is offset in the second direction from resonator 630A by a first Y axis offset 1, and similarly, resonator 630C is offset in the second direction from resonator 630B by a second Y axis offset 2. The first Y axis offset 1 can be the same or a different length than the second Y axis offset 2 in various exemplary aspects. Likewise, resonator 630B is offset in the first direction from resonator 630A by a first X axis offset 1, and similarly, resonator 630C is offset in the first direction from resonator 630B by a second X axis offset 2. The first X axis offset 1 can be the same or a different length than the second X axis offset 2 in various exemplary aspects.

Moreover, in the exemplary aspect of FIG. 6E, the length L/3 of each of the three resonators can be one third of the length L of the single resonator structure 630 of FIG. 6A. That is, the total length of these three resonators 630A, 630B and 630C is equal to a corresponding filter device having a single resonator structure 600A as shown in FIG. 6A. However, it is also noted that the cascading structure shown in FIG. 6E is not limited to three resonators and may be extended to more resonators. Moreover, the total length of the plurality of resonators can be more or less than a single resonator structure 600A of the corresponding filter device in an alternative aspect.

Furthermore, according to various exemplary aspects, any of the parallel structures of FIGS. 6B-6E may be extended or accumulated as tile units to add more resonators and subsequently further reduce the length of each individual resonator in the structure. In other words, the exemplary two resonators 630A and 630B shown in FIG. 6B may be divided into additional resonators and formed in a cascading layout and, for example, can be configured such that the total length of all resonators is the same as the corresponding filter device having a single resonator, such as resonator structure 600A of FIG. 6A. As noted above, other parallel resonator configurations may be possible, as long as such configurations reduce resonator aperture and/or reduce device dimensions.

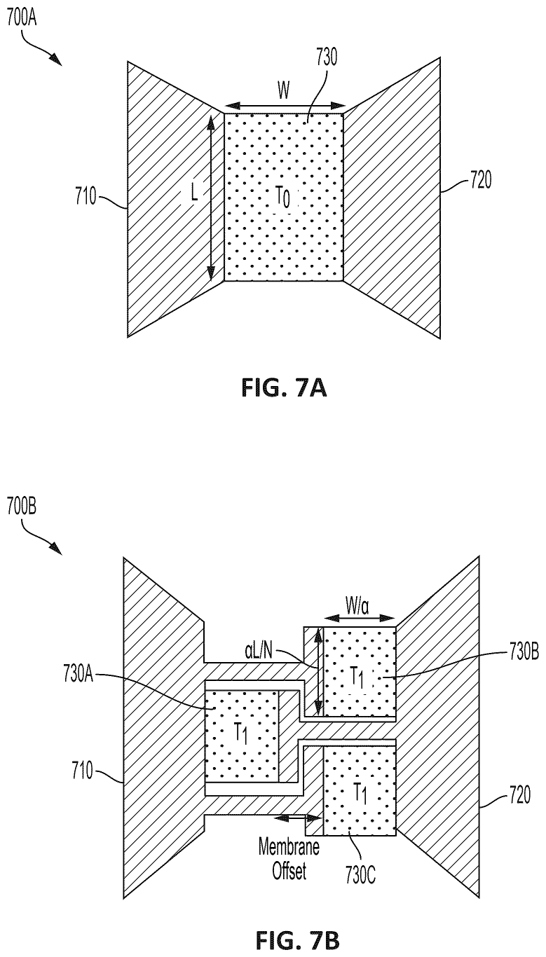

In fact, other design advantages may result from breaking down a single resonator structure to multiple parallelized resonators, even if an overall area of the device (i.e., the IDT area, which can be the IDT aperture times the IDT length) remains constant. For example, using a parallelized multi-resonator configuration may achieve improved thermal transport and improved power handling. FIG. 7A shows a single resonator device 700A area having a width w and a length L, where generally the temperature T₀ of the resonator 730 is proportional to P(W/L), where P is the power applied to the single resonator device 700A.

In contrast, FIG. 7B shows a parallelized configuration 700B of the single resonator of FIG. 7A including three resonators 730A, 730B and 730C. It should be appreciated that the exemplary aspect of FIG. 7B is a rotated version of the configuration described above with respect to FIG. 6C. Also, similar to wiring terminals 610 and 620 as described above, the single resonator device 700A and the parallelized configuration 700B both includes wiring terminals 710 and 720, respectively, which are provided as electrical contacts for applying the voltages to acoustic resonator(s) as described herein. Moreover, in the exemplary aspect of the parallelized configuration 700B, the width of each of the devices in FIG. 7B is reduced to W/a and the length is reduced to αL/N. The areas labeled with T1 in FIG. 7B represent the piezoelectric membranes (or layers) of each device and the horizontal offset is labeled as “membrane offset.”

As shown in FIG. 7B, the temperature T₁ of each of the three resonators 730A, 730B and 730C is proportional to T₀/α², which represents a general decrease of the temperature of each device, as compared to the configuration of the single resonator device 700A of FIG. 7A. The temperature decrease represented by T₁ is not primarily dependent on the number of devices used in the parallelized structure but is instead based on the reduction of the aperture dimensions. However, for a large number of parallel devices, additional heat dissipation may occur through the edges of the piezoelectric membranes, as a secondary effect.

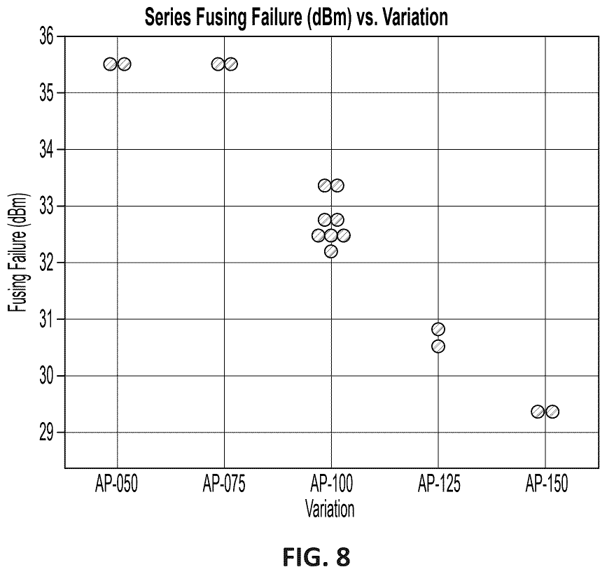

While the temperature functions described with respect to FIGS. 7A and 7B assume a primarily lateral heat flow and a structure where the thickness of a metal IDT layer is equal to or similar to the thickness of the piezoelectric layer, reducing the dimensions of the aperture in “thin metal” devices having a metal IDT layer that is significantly thinner than the piezoelectric layer may also be effective in improving power handling. FIG. 8 is a graph plotting the fusing failure points of several variations of devices having thin metal IDT layers and various configurations and aperture dimensions.

Fusing failure or series fusing failure points in the context of FIG. 8 refer to a power level, measured in dBm in FIG. 8, at which a series circuit of acoustic resonators fails to operate properly due to the high level of applied power. The failure can result in a loss of resonance frequency, a decrease in the quality factor below an acceptable threshold, or complete device breakdown. Table 1 below defines the aperture dimensions of the variations listed on the x axis of FIG. 8.

TABLE 1

| Variation | Aperture Width (μm) | Aperture Length (μm) |
|---|---|---|
| AP-050 | 29.8 | 282.0 × 2 |
| AP-075 | 41.7 | 190.8 × 2 |
| AP-100 | 53.6 | 282.0 |
| AP-125 | 65.5 | 229.2 |
| AP-150 | 77.4 | 190.8 |

As shown in Table 1, the variations in the listed order have increasing aperture widths. With respect to aperture lengths, the first two rows in Table 1 (AP-050 and AP-075) represent a parallelized structure including two resonators connected in parallel and having the listed dimensions, in addition to a series resonator connected in series. The last three rows (AP-100, AP-125, and AP-150) represent a single tested resonator connected to the series resonator. The same series resonator was used for testing all variations.

FIG. 8 shows power levels at which series fusing failure occurs for each of the variations. As shown, the two variations having two parallel resonators (AP-050 and AP-075) failed at the highest power level, reaching the test limit. These variations also had the smallest width. Among the single tested resonator variations (AP-100, AP-125, and AP-150), fusing failure power levels decreased with increasing aperture widths.

Accordingly, FIG. 8 shows the improved power handling that results from decreasing aperture dimensions, including aperture width. Additionally, FIG. 8 shows that the parallelized multi-resonator structures described above are consistent with improved power durability at least due to supporting decreased aperture dimensions. Although the narrowest aperture width shown in FIG. 8 is 29.8 μm, the aperture width of each resonator in a parallelized multi-resonator structure may be 20 μm, for example.

Replacing a single resonator structure with large aperture dimensions with a parallelized multi-resonator structure has performance trade-offs that may be considered in light of particular device specifications. For example, single resonator layouts provide increased coupling due to lower loss than the parallelized multi-resonator design described above. Accordingly, a single resonator structure may be selected to achieve target bandwidth in certain applications.

The additional parasitic losses associated with using the parallelized multi-resonator configurations result in slight peak loss, reduced coupling, and Q degradation. These considerations may be weighed against the improved heat conduction and power handling, as well as potentially reduced device area that may be achieved when using the parallelized design, as described above. Accordingly, if maximal coupling of resonators is not a primary device requirement, the performance trade-offs associated with using the parallelized configurations can be acceptable.

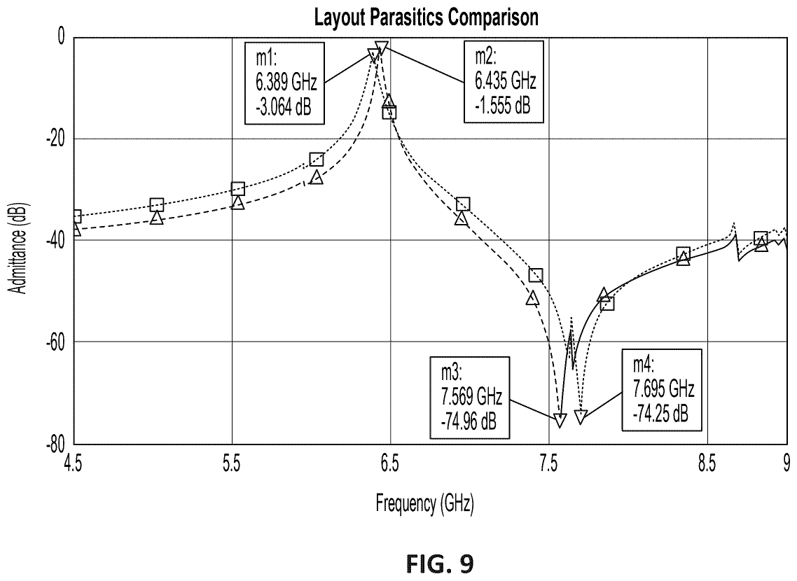

FIG. 9 shows the performance difference between a single resonator and a parallelized multi-resonator design, which is simulated using finite element method (FEM) simulation techniques, and where the triangle curve corresponds to the parallelized multi-resonator design and the square curve corresponds to the single resonator design. The Y axis represents admittance in dB against frequency in GHz on the X axis. The single resonator design whose performance is shown on the square curve has an acoustic track area of 12852 μm², which represents the total aperture area (i.e., the length of the aperture multiplied by the width of the aperture). The coupling coefficient of the single resonator design of the square curve is 0.31.

On the other hand, the parallelized multi-resonator design of the triangle curve has a slightly lower coupling coefficient of 0.28. However, the acoustic track area, or total aperture area, is likewise lowered to 9450 μm². Both the single resonator and multi-resonator configurations of FIG. 9 have the same effective shunt capacitance. FIG. 9 shows the resonance and anti-resonance frequencies and admittance values associated with both configurations.

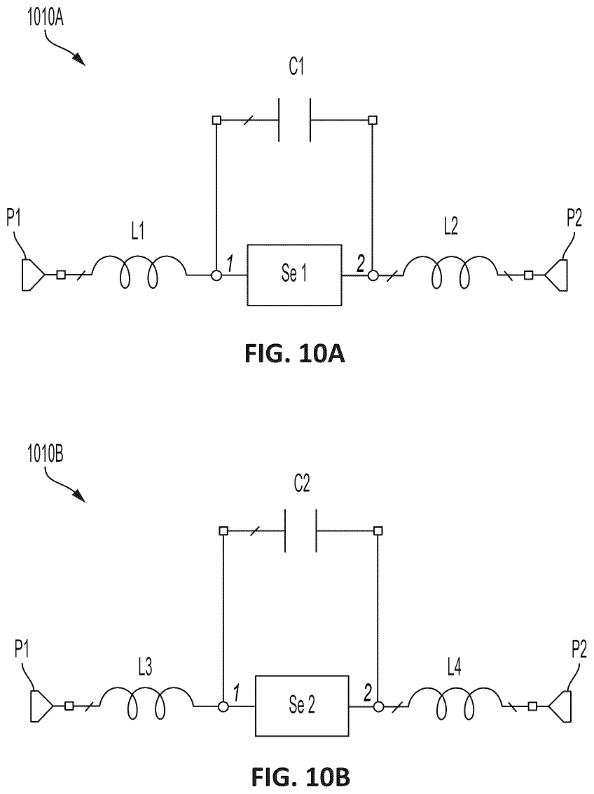

FIGS. 10A and 10B show parasitic measurement differences between the parallelized multi-resonator and single resonator designs that are at least partially responsible for the performance differences shown in FIG. 9. FIG. 10A illustrates a circuit diagram for a parallelized multi-resonator 1010A according to an exemplary aspect, whereas FIG. 10B refers to the single resonator design 1010B as “Typical Resonator,”, such as the XBAR described above with respect to FIG. 1A. Both FIGS. 10A and 10B show lumped parasitic measurements, including series inductance and parallel capacitance, associated with each configuration.

The circuit diagram of FIG. 10A includes a first port P1 (e.g., an input or output port) and a second port P2 (e.g., an input or output port). A series resonator Se1, which can include the parallelized multi-resonator described herein, is coupled in series between inductors L1 and L2. Moreover, a capacitor C1 is coupled in parallel to the series resonator Se1. Similarly, the circuit diagram of FIG. 10B includes a first port P1 (e.g., an input or output port) and a second port P2 (e.g., an input or output port). A series resonator Se2, which can be a single resonator configuration, such as that in FIG. 6A, is coupled in series between inductors L3 and LA. Moreover, a capacitor C2 is coupled in parallel to the series resonator Se2.

According to an exemplary aspect of FIGS. 10A and 10B, each of the ports P1 and P2 can be considered to have an input impedance of 50 Ohms. Moreover, the lumped parasitic measurements are generally degraded when moving from the single resonator design to the parallelized multi-resonator. For example, the series inductance decreases from 0.068 nH (single resonator circuit of FIG. 10B) to 0.055 nH (parallelized multi-resonator circuit of FIG. 10A). Additionally, the parallel capacitance increases from 0.018 pF (single resonator circuit of FIG. 10B) to 0.034 pF (parallelized multi-resonator circuit of FIG. 10A). Accordingly, the changes in the lumped parasitic measurements between single resonator designs and the parallelized multi-resonator designs, as shown in FIGS. 10A and 10B provide another set of trade-offs to be considered for determining whether the parallelized multi-resonator design is appropriate for particular device applications.

In general, it is noted that the configurations and data associated with FIGS. 6A-10B capture some of the advantages and trade-offs of splitting a single resonator configuration into multiple resonators with reduced aperture sizes. Such advantages include decreased overall device area, improved power handling, and improved heat conduction. Accordingly, splitting a single resonator configuration into multiple parallel resonator devices according to an exemplary aspect facilitates design decisions where the advantages of the parallelized design outweigh the trade-offs.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
at least two resonators electrically connected in parallel, each of the at least two resonators including:
a piezoelectric layer, and
an interdigital transducer (IDT) having a pair of busbars that extend in a first direction and a plurality of interleaved fingers extending from the pair of busbars and that are on a surface of the piezoelectric layer,
wherein at least one busbar of the pair of busbars of a first resonator of the at least two resonators overlaps at least one busbar of the pair of busbars of a second resonator of the at least two resonators in a second direction substantially orthogonal to the first direction, and the pair of busbars of the first resonator does not overlap the pair of busbars of the second resonator in the first direction.

2. The filter device of claim 1, wherein the first direction extends along a first axis and the pair of busbars of each of the first and second resonators overlap in the second direction, such that a first imaginary line extending in a second axis perpendicular to the first axis intersects the at least one busbar of both the first resonator and the second resonator.

3. The filter device of claim 2, wherein a portion of the second resonator is not aligned with a portion of the first resonator in a plan view such that a second imaginary line extending in the second direction intersects the portion of the first resonator and not the portion of the second resonator.

4. The filter device of claim 1, wherein the at least two resonators comprise a physical layout such that:
(i) lengths of the at least two resonators extend in the first direction and the plurality of interleaved fingers extend in the second direction, and
(ii) a position of the first resonator is offset in the second direction from a position of the second resonator of the at least two resonators, such that the respective lengths of the at least two resonators are not aligned in a same axis in the first direction, and
(iii) the length of the first resonator is offset in the first direction from the length of the second resonator, such that the respective lengths of the first and second resonators only partially overlap each in the second direction.

5. The filter device of claim 4, wherein each of the at least two resonators comprise a substrate, and the piezoelectric layer attached to the substrate by one or more intermediate layers.

6. The filter device of claim 4, wherein the lengths of each of the first resonator and the second resonator are defined by a length of the at least one busbar of the pair of busbars, respectively.

7. The filter device of claim 4, wherein the lengths of each of the first resonator and the second resonator are defined by a distance between outermost fingers of the plurality of interleaved fingers of the IDT of the respective resonator.

8. The filter device of claim 5, wherein each of the at least two resonators comprises a cavity in at least one of the substrate and the one or more intermediate layers, each cavity comprising opposing ends in the first direction, and the length of each of the first resonator and the second resonator is defined by a distance between the opposing ends of the cavity in the first direction.

9. The filter device of claim 1, wherein the at least two resonators are sub-resonators of a bulk acoustic resonator of a ladder filter circuit each have a same number of interleaved fingers of the IDT and a substantially same length as each other.

10. The filter device according to claim 1, wherein the piezoelectric layer and the IDT of each of the at least two resonators are configured such that a radio frequency signal applied to the IDT excites a primarily shear acoustic mode in the piezoelectric layer, the primarily shear acoustic mode being a bulk shear mode in which acoustic energy propagates along a direction substantially orthogonal to a surface of the piezoelectric layer, which is orthogonal to a direction of an electric field excited primarily laterally in the piezoelectric layer created by the plurality of interleaved fingers of the IDT.

11. A filter device comprising:
at least two resonators electrically connected in parallel, each of at least two resonators including:
a piezoelectric layer, and
an interdigital transducer (IDT) including a plurality of interleaved fingers on the piezoelectric layer,
wherein:
lengths of the at least two resonators extend in a first direction,
the length of a first resonator of the at least two resonators is offset in a second direction orthogonal to the first direction from the length of a second resonator of the at least two resonators, such that the at least two resonators are not aligned in a same axis that extends in the first direction, and
the length of the first resonator is offset in the first direction from the length of the second resonator, such that the lengths of the first and second resonators partially overlap each other relative to the second direction.

12. The filter device of claim 11, wherein:
a portion of the second resonator is aligned with a portion of the first resonator in a plan view such that a first imaginary line extending in the second direction intersects the respective portions of the first and second resonators, and
the second resonator includes an additional portion that is not aligned with an additional portion of the first resonator in the plan view such that a second imaginary line extending in the second direction intersects the additional portion of only one of the first resonator and the second resonator.

13. The filter device of claim 11, wherein the IDT of each of the first resonator and the second resonator comprise a pair of busbars extending substantially in the first direction, and the lengths of each of the first resonator and the second resonator are defined by a length of at least one busbar of the busbars of each of the first and second resonators.

14. The filter device of claim 11, wherein:
each of the at least two resonators comprise a substrate, and the piezoelectric layer attached to the substrate by one or more intermediate layers, and
each of the at least two resonators comprises a cavity in at least one of the substrate and the one or more intermediate layers, each cavity comprising opposing ends in the first direction, and the length of each of the first resonator and the second resonator is defined by a distance between the opposing ends of the cavity in the first direction.

15. The filter device of claim 11, wherein the lengths of each of the first resonator and the second resonator are defined by a distance between outermost fingers of the plurality of interleaved fingers of the IDT of the respective resonator.

16. The filter device of claim 11, wherein the at least two resonators are sub-resonators of a bulk acoustic resonator of a ladder filter circuit each have a same number of interleaved fingers of the IDT and the length of the at least two resonators is substantially the same.

17. The filter device according to claim 11, wherein the piezoelectric layer and the IDT of each of the at least two resonators are configured such that a radio frequency signal applied to the IDT excites a primarily shear acoustic mode in the piezoelectric layer, the primarily shear acoustic mode being a bulk shear mode in which acoustic energy propagates along a direction substantially orthogonal to a surface of the piezoelectric layer, which is transverse to a direction of an electric field excited laterally in the piezoelectric layer created by the plurality of interleaved fingers of the IDT.

18. The filter device of claim 11, wherein:
the at least two resonators include three resonators,
a portion of the second resonator overlaps a portion of the first resonator in a plan view such that a first imaginary line extending in the second direction intersects the respective portions of the first and second resonators,
an additional portion of the second resonator overlaps a portion of a third resonator in the plan view such that a second imaginary line extending in the second direction intersects the additional portion of the second resonator and the portion of the third resonator and does not intersect the first resonator, and
the first resonator and the third resonator are positioned such that a third imaginary line extending in the first direction intersects the first and third resonators and not the second resonator.

19. A filter device comprising:
a plurality of resonators electrically connected in parallel, wherein:
each of the plurality of resonators includes an interdigital transducer (IDT) on a surface of a piezoelectric layer and having at least one busbar extending in a first direction,
each IDT having a length measured in the first direction that is defined by a distance between a first end and a second end of the at least one busbar in the first direction,
the filter device corresponding to a total IDT length that is equal to a sum of the lengths of the IDT of each of the plurality of resonators,
wherein the length of a first resonator of the plurality of resonators at least partially overlaps the length of a second resonator of the plurality of resonators in the second direction, such that the first resonator and the second resonator are not aligned in a same axis that extends in the first direction, and
wherein a distance in the first direction between a pair of imaginary lines extending in the second direction that intersect the first end of the at least one busbar of the first resonator and the second end of the at least one busbar of the second resonator is less than the total IDT length.

20. The filter device of claim 19, wherein the plurality of resonators are sub-resonators of a bulk acoustic resonator of a ladder filter circuit each have a same number of interleaved fingers of the IDT and the length of the at least two resonators is substantially the same.
